(19) United States
(12) Patent Application Publication
(10) Pub. No.: US 2025/0309040 A1
(43) Pub. Date: Oct. 2, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wen-Jung TSAI, Taichung City (TW); Nai-Hao KAO, Taichung City (TW); Liang-Yi HUNG, Taichung City (TW)

(21) Appl. No.: 18/817,300

(22) Filed: Aug. 28, 2024

(30) Foreign Application Priority Data
Apr. 1, 2024 (TW) 113112391

(51) Int. Cl. H01L 23/373; H01L 23/367

(52) U.S. Cl. CPC H01L 23/3736; H01L 23/3672

(57) ABSTRACT

Provided are an electronic package and a manufacturing method thereof, including an electronic module disposed on a first surface of a carrier structure, a retaining wall structure mounted on the first surface of and positioned an outside the electronic module with a predetermined distance. A heat dissipation material is formed to cover the electronic module and be positioned between the retaining wall structure and the electronic module. The heat dissipation material formed between the retaining wall structure and the electronic module is with a predetermined thickness. A heat dissipation structure is disposed on the heat dissipation material and the retaining wall structure, and a fluid regulation space is formed between the heat dissipation structure, the heat dissipation material and the retaining wall structure, and is communicated with at least a vent formed in the heat dissipation structure for heat dissipation.

### CROSS-REFERENCE TO RELATED APPLICATIONS

The present application is based upon and claims the right of priority to TW Patent Application No. 113112391, filed Apr. 1, 2024, the disclosure of which is hereby incorporated by reference herein in its entirety for all purposes.

### BACKGROUND

### 1. Technical Field

The present disclosure relates to a semiconductor device, and more particularly, to an electronic package that has heat dissipation structure and a manufacturing method thereof.

### 2. Description of Related Art

As the demand for functionality and processing speed of electronic products increases, electronic components and electronic circuits with a higher density are required for a semiconductor chip served as a core component of electronic product. Therefore, a greater amount of heat energy would be generated during operation of the semiconductor chip. Furthermore, since the traditional encapsulant covering the semiconductor chip is a poor material for heat transfer with a thermal conductivity of merely 0.8 watts/(meter Kelvin) (W·m⁻¹·k⁻¹) (i.e., inefficient heat dissipation). Therefore, if the heat generated by the semiconductor chip cannot be effectively dissipated, a damage to the semiconductor chip and an issue of product reliability issues occur.

Therefore, in order to quickly dissipate heat energy to the outside, a heat sink (or a heat spreader) is generally configured in the semiconductor package in the industry. The heat sink is usually bonded to the back of the semiconductor chip by heat dissipation glue, such as a thermal interface material (TIM), to dissipate the heat generated by the semiconductor chip through the heat dissipation glue and heat sink. Furthermore, the top surface of the heat sink is normally exposed from the encapsulant or directly exposed to the atmosphere to achieve an effect of heat dissipation.

However, the TIM layer in conventional semiconductor packages can be a liquid metal which is a fluid and expands at high temperatures. Therefore, the liquid metal cannot be stably laid on the inactive surface of the semiconductor chip and may even overflow out of the semiconductor package, and thus other elements outside the semiconductor package would be contaminated.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure having a first surface and a second surface opposite to the first surface; an electronic module disposed on the first surface of the carrier structure; a retaining wall structure mounted on the first surface of the carrier structure and surroundingly positioned outside the electronic module by a predetermined distance; a heat dissipation material formed on the electronic module and in a space between the electronic module and the retaining wall structure; and a heat dissipation structure disposed on the heat dissipation material and the retaining wall structure and shielding the electronic module.

The present disclosure also provides a method of manufacturing an electronic package. The method comprises: providing a carrier structure having a first surface and a second surface opposite to the first surface, and disposing an electronic module on the first surface of the carrier structure; mounting a retaining wall structure on the first surface of the carrier structure, in a manner that the retaining wall structure is surroundingly positioned outside the electronic module and by a predetermined distance; forming a heat dissipation material on the electronic module and in a space between the electronic module and the retaining wall structure, for the heat dissipation material to cover the electronic module; and disposing a heat dissipation structure on the heat dissipation material and the retaining wall structure, so as for the heat dissipation structure to shield the electronic module.

In the aforementioned electronic package and method, the heat dissipation structure comprises: a heat sink disposed on the heat dissipation material and the retaining wall structure; and a support part with one end erected on the first surface of the carrier structure and annularly disposed on the outside of the retaining wall structure and the other end of the support part connected to the heat sink.

In the aforementioned electronic package and method, a fluid regulation space is formed between the heat dissipation structure, the heat dissipation material and the retaining wall structure.

In the aforementioned electronic package and method, the heat dissipation structure is formed with at least a vent, and the fluid regulation space is communicated with the at least a vent.

In the aforementioned electronic package and method, the electronic module has an electronic component, a carrier and a package body and the electronic component is disposed on the carrier and covered by the package body.

In the aforementioned electronic package and method, the heat dissipation structure is disposed on the retaining wall structure via a binding material.

In the aforementioned electronic package and method, the heat dissipation material is a liquid metal.

In the aforementioned electronic package and method, further comprising: forming a metal layer on the first surface of the carrier structure, the outside of the electronic module, an inside of the retaining wall structure, and an inside of the heat dissipation structure, such that the heat dissipation material is confined by the metal layer.

In the aforementioned electronic package and method, the metal layer is a nickel-gold material.

In the aforementioned electronic package and method, an intermetallic compound layer is formed between the metal layer and the heat dissipation material.

As can be understood from the above, in the electronic package and manufacturing method of the present disclosure, a confined space is formed between the carrier structure, the retaining wall structure, the electronic module and the heat dissipation structure, thereby the heat dissipation material such as a liquid metal covers the electronic module (the five sides of the electronic module). In addition, the metal layer is formed on the carrier structure, and between the electronic module and the retaining wall structure, for confining the heat dissipation material therein, such that an intermetallic compound is formed between the metal layer and the heat dissipation material to limit the flow of the heat dissipation material while improving heat dissipation efficiency.

### BRIEF DESCRIPTION OF THE DRAWINGS

FIG. 1 to FIG. 4 are schematic cross-sectional views of the manufacturing method of the electronic package of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

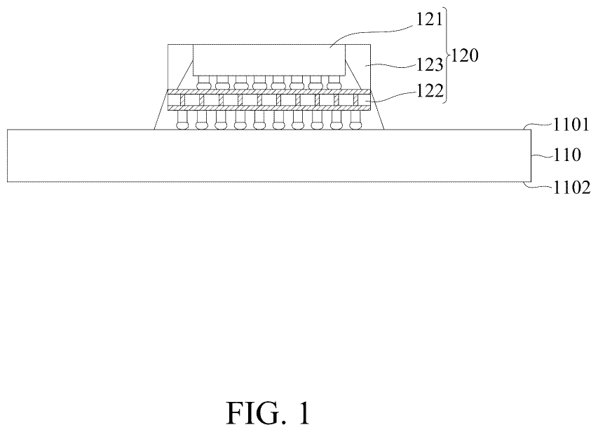

FIG. 1 to FIG. 4 are schematic cross-sectional views of the manufacturing method of an electronic package 100 of the present disclosure.

As shown in FIG. 1, a carrier structure 110 has a first surface 1101 and a second surface 1102 opposite to the first surface 1101, and an electronic module 120 is disposed on the first surface 1101 of the carrier structure 110.

In this embodiment, the carrier structure 110 is, for example, a package substrate with a core layer and a circuit structure or a coreless circuit structure, which forms a circuit layer on a dielectric material, such as a fan-out type redistribution layer (RDL), and the electronic module 120 is electrically connected to the carrier structure 110.

In this embodiment, the electronic module 120 has an electronic component 121, a carrier 122 and a package body 123. The electronic component 121 is an active element, an inactive element, or a combination thereof. The active element is a semiconductor chip, and the inactive element is a resistor, a capacitor, or an inductor. The carrier 122 is, for example, a substrate, a lead frame or an interposer, such that the electronic component 121 is disposed on the carrier 122. The material of the package body 123 can be a dielectric material such as polybenzoxazole (PBO), polyimide (PI), prepreg (PP) or other, and the electronic component 121 is covered by the package body 123. In other embodiments, the electronic module 120 may also only be composed of the electronic component.

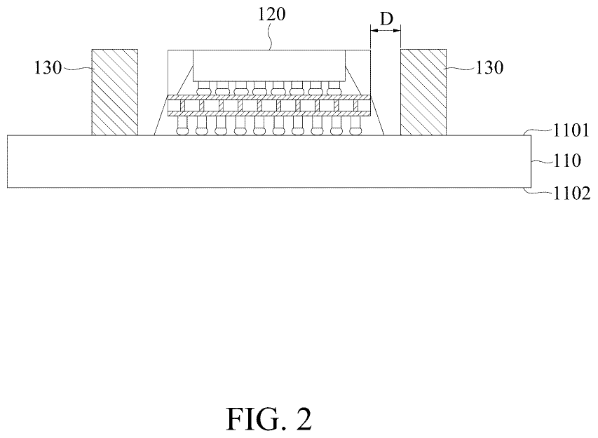

As shown in FIG. 2, a retaining wall structure 130 is erected on the first surface 1101 of the carrier structure 110. The retaining wall structure 130 is annularly positioned outside the electronic module 120 and is spaced from the electronic module 120 by a predetermined distance D.

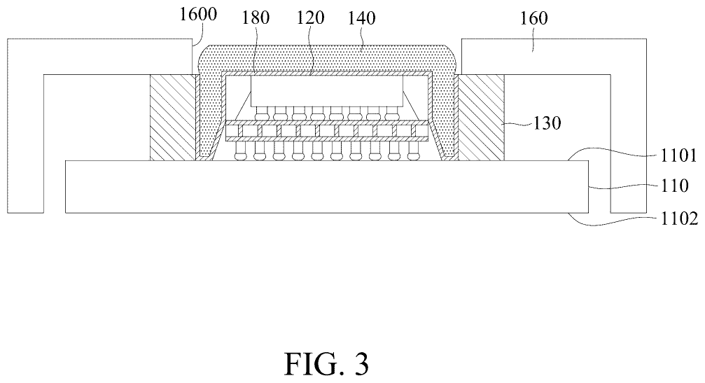

As shown in FIG. 3, a shielding member 160 is disposed on the carrier structure 110. The shielding member 160 is configured with an opening 1600 corresponding to the electronic module 120 and the retaining wall structure 130, and a metal layer 180 is formed on the outer surface of the electronic module 120, and the outer surface of the carrier structure 110 along with the inner surface of the retaining wall structure 130 between the electronic module 120 and the retaining wall structure 130, thereby the opening 1600 is exposed from the metal layer 180. Afterwards, the opening 1600 is filled with a heat dissipation material 140, and the heat dissipation material 140 is formed on the electronic module 120 and between the electronic module 120 and the retaining wall structure 130 to fully cover the electronic module 120.

In this embodiment, the metal layer 180 is, for example, a nickel/gold layer, and the heat dissipation material 140 is a thermal interface material (TIM), such as a low-temperature melting thermal conductive material, which can be a liquid metal. A material of the liquid metal comprises an indium metal. The present disclosure can effectively increase the heat dissipation area of the liquid metal for the electronic module 120 by fully covering the five surfaces (upper side, front side, front side, left side, and right side) of the electronic module 120 with the heat dissipation material 140. In addition, the material of the retaining wall structure 130 can be a metal, an epoxy, or a special porous structure allowing air to pass through without fluid flowing through, which effectively blocks the heat dissipation material 140 inside the retaining wall structure 130.

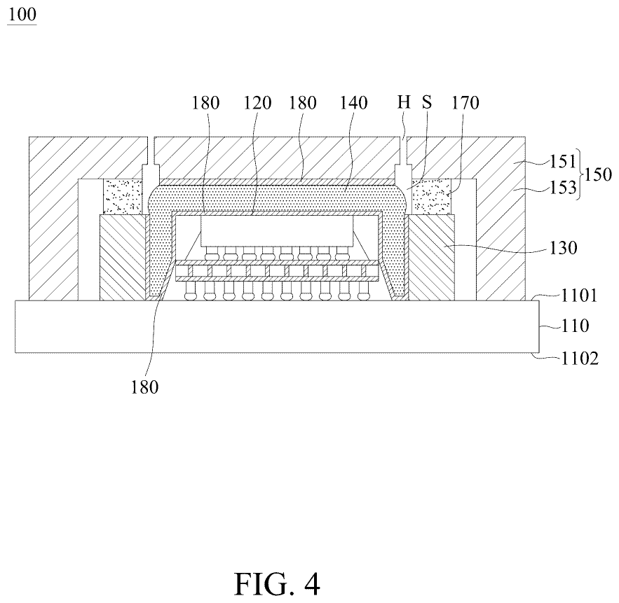

As shown in FIG. 4, a heat dissipation structure 150 is disposed on the heat dissipation material 140 and the retaining wall structure 130 and shields the electronic module 120 to obtain the electronic package 100 of the present disclosure.

In this embodiment, the heat dissipation structure 150 comprises a heat sink 151 and a support part 153 erected on the heat sink 151 that can be disposed on the retaining wall structure 130 through a binding material 170, and the support part 153 is erected on the carrier structure 110.

In this embodiment, the heat sink 151 of the heat dissipation structure 150 can be attached to the heat dissipation material 140 via the metal layer 180. Accordingly, the surroundings of the heat dissipation material 140 is covered with the metal layer 180 that is a back side metallization (BSM), thereby the heat dissipation material 140 (liquid metal) can form an intermetallic compound (IMC) with the metal layer 180 to limit the flows of the heat dissipation material 140 (liquid metal). In addition, one end of the support part 153 of the heat dissipation structure 150 can be erected on the first surface 1101 of the carrier structure 110 through a glue material and annularly positioned on the outside of the retaining wall structure 130, and thus the support part 153 can provide a supporting force to the heat sink 151.

In this embodiment, a fluid regulation space S (which can be called an expansion reserved area) can be formed between the heat dissipation structure 150 (the heat sink 151 therein), the retaining wall structure 130, the heat dissipation material 140 and the binding material 170. The fluid regulation space S is connected to at least a vent H formed on the heat dissipation structure 150 (the heat sink 151 therein). When the electronic component 121 operates, under the circumstance that the heat dissipation material 140 such as the liquid metal expands in volume, the fluid regulation space S can provide an accommodating space for volume expansion of the liquid metal, and a thermal energy generated from operation of the electronic component 121 is discharged through connection of the vent H formed in the heat dissipation structure 150. The fluid regulation space S can not only effectively prevent the heat dissipation material 140 from overflowing from the electronic package 100 and avoid other elements outside the electronic package 100 from contamination, but also avoid a popcorn issue from occurring by pressure regulation of the fluid regulation space S. In addition, the metal layer 180 covers the heat dissipation material 140 by forming the metal layer 180 of the nickel-gold material on the first surface 1101 of the carrier structure 110, the outside of the electronic module 120, the inside of the retaining wall structure 130 and the inside of the heat dissipation structure 150, an intermetallic compound is thus formed between the metal layer 180 and the heat dissipation material 140, thereby a metallic bonding and an adhesion are formed. Consequently, the flow of the heat dissipation material 140 is limited, and the heat dissipation material 140 formed by the liquid metal can be effectively prevented from overflowing from the electronic package 100.

The present disclosure further provides the electronic package 100, which comprises: the carrier structure 110, the electronic module 120, the retaining wall structure 130, the heat dissipation material 140 and the heat dissipation structure 150. The carrier structure 110 has the first surface 1101 and the second surface 1102 opposite to the first surface 1101. The electronic module 120 is disposed on the first surface 1101 of the carrier structure 110. The retaining wall structure 130 is erected on the first surface 1101 of the carrier structure 110 and is annularly disposed on the outside of the electronic module 120 and spaced the predetermined distance D. The heat dissipation material 140 is disposed on the upper side and the sides of the electronic module 120 and is located between the retaining wall structure 130 and the electronic module 120. The heat dissipation structure 150 is disposed on the heat dissipation material 140 and shields the electronic module 120. In addition, the fluid regulation space S is provided between the heat dissipation structure 150, the heat dissipation material 140 and the retaining wall structure 130, and the fluid regulation space S is connected to the at least one vent H disposed on the heat dissipation structure 150.

In one embodiment, the heat dissipation structure 150 comprises: the heat sink 151 disposed on the heat dissipation material 140 and the retaining wall structure 130; the support part 153 with one end erected on the first surface 1101 of the carrier structure 110 and annularly disposed on the outside of the retaining wall structure 130 and the other end connected to the heat sink 151. The fluid regulation space S is formed between the heat sink 151, the retaining wall structure 130 and the heat dissipation material 140.

In one embodiment, the electronic module 120 comprises: the electronic component 121, the carrier 122 and the package body 123, and the electronic component 121 is disposed on the carrier 122 and covered by the package body 123.

In one embodiment, the heat sink 151 is disposed on the retaining wall structure 130 through the binding material 170.

In one embodiment, the heat dissipation material 140 is a liquid metal, and a material of the liquid metal comprises an indium metal.

In one embodiment, the electronic package 100 further comprises: the metal layer 180 disposed on the first surface 1101 of the carrier structure 110, the outside of the electronic module 120, the inside of the retaining wall structure 130 and the inside of the heat dissipation structure 150 and covering the heat dissipation material 140.

In one embodiment, the metal layer 180 is a nickel-gold material.

In one embodiment, an intermetallic compound layer is formed between the metal layer 180 and the heat dissipation material 140 for limitinging a flow of the heat dissipation material 140.

In view of the above, in the electronic package and manufacturing method of the present disclosure, a confined space is formed between the carrier structure, the retaining wall structure, the electronic module and the heat dissipation structure, and thus the heat dissipation material such as the liquid metal covers the upper side and the sides of the electronic module (five sides of the electronic module). Also, the metal layer is disposed on the carrier structure, the outside of the electronic module, the inside of the retaining wall structure and the inside of the heat dissipation structure to contact the heat dissipation material, an intermetallic compound is thus formed between the metal layer and the heat dissipation material, thereby limiting the flow of the heat dissipation material while improving heat dissipation efficiency.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a first surface and a second surface opposite to the first surface;
an electronic module disposed on the first surface of the carrier structure;
a retaining wall structure mounted on the first surface of the carrier structure, annularly positioned outside the electronic module and spaced from the electronic module by a predetermined distance;
a heat dissipation material formed on the electronic module and between the electronic module and the retaining wall structure to cover an upper side and sides of the electronic module; and
a heat dissipation structure disposed on the heat dissipation material and the retaining wall structure for shielding the electronic module.

2. The electronic package of claim 1, wherein the heat dissipation structure comprises:
a heat sink disposed on the heat dissipation material and the retaining wall structure; and
a support part with one end of the support part erected on the first surface of the carrier structure and annularly positioned outside the retaining wall structure, and the other end of the support part connected to the heat sink.

3. The electronic package of claim 1, further comprising a fluid regulation space formed between the heat dissipation structure, the heat dissipation material and the retaining wall structure.

4. The electronic package of claim 3, wherein at least a vent is formed on the heat dissipation structure, and the fluid regulation space is communicated with the at least a vent.

5. The electronic package of claim 1, wherein the electronic module comprises: an electronic component, a carrier and a package body, and the electronic component is disposed on the carrier and encapsulating by the package body.

6. The electronic package of claim 1, wherein the heat dissipation structure is disposed on the retaining wall structure via a binding material.

7. The electronic package of claim 1, wherein the heat dissipation material is liquid metal.

8. The electronic package of claim 1, further comprising: a metal layer formed on the first surface of the carrier structure, the outside of the electronic module, an inside of the retaining wall structure, and an inside of the heat dissipation structure, such that the heat dissipation material is confined by the metal layer.

9. The electronic package of claim 8, wherein the metal layer is a nickel-gold material.

10. The electronic package of claim 8, wherein an intermetallic compound layer is formed between the metal layer and the heat dissipation material.

11. A method of manufacturing an electronic package, comprising:
providing a carrier structure having a first surface and a second surface opposite to the first surface, for an electronic module to be disposed on the first surface of the carrier structure;
mounting a retaining wall structure on the first surface of the carrier structure, in a manner that the retaining wall structure surrounds the electronic module and is spaced from the electronic module by a predetermined distance;
forming a heat dissipation material on the electronic module and in a space between the electronic module and the retaining wall structure, for the heat dissipation material to cover the electronic module; and
disposing a heat dissipation structure on the carrier structure, in a manner that the heat dissipation structure is attached to the heat dissipation material and the retaining wall structure, so as for the heat dissipation structure to shield the electronic module.

12. The method of claim 11, wherein the heat dissipation structure comprises:
a heat sink positioned on the heat dissipation material and the retaining wall structure; and
a support part with one end erected on the first surface of the carrier structure and surroundingly positioned outside the retaining wall structure and the other end connected to the heat sink.

13. The method of claim 11, wherein a fluid regulation space is formed between the heat dissipation structure, the heat dissipation material and the retaining wall structure.

14. The method of claim 13, wherein at least a vent is formed on the heat dissipation structure, and the fluid regulation space is communicated with the at least a vent.

15. The method of claim 11, wherein the electronic module comprises an electronic component, a carrier and a package body, and the electronic component is disposed on the carrier and encapsulating by the package body.

16. The method of claim 11, wherein the heat dissipation structure is attached to the retaining wall structure via a binding material.

17. The method of claim 11, wherein the heat dissipation material is liquid metal.

18. The method of claim 11, further comprising: forming a metal layer on the first surface of the carrier structure, the outside of the electronic module, an inside of the retaining wall structure, and an inside of the heat dissipation structure, in a manner that the heat dissipation material is confined by the metal layer.

19. The method of claim 18, wherein the metal layer is a nickel-gold material.

20. The method of claim 18, wherein an intermetallic compound layer is formed between the metal layer and the heat dissipation material.
